(19) United States
(12) Patent Application Publication
(10) Pub. No.: US 2026/0372161 A1
(43) Pub. Date: Nov. 19, 2026

(54) SEMICONDUCTOR DEVICE

(71) Applicant: ROHM Co., LTD., Kyoto (JP)

(72) Inventor: Naoyuki Sano, Kyoto (JP)

(21) Appl. No.: 19/458,054

(22) Filed: Jan. 23, 2026

(30) Foreign Application Priority Data
Jan. 27, 2025 (JP) 2025-011385

(51) Int. Cl. H10W 72/60

(52) U.S. Cl. CPC H10W 72/637; H10W 72/652

(57) ABSTRACT

A semiconductor device includes a conductive member and a semiconductor element that is positioned on one side of the conductive member in a first direction and is conductive to the conductive member. The semiconductor element has an element surface facing the conductive member, and a first electrode and a second electrode projecting from the element surface. The area of the first electrode is larger than the area of the second electrode when viewed in the first direction. The dimension of the first electrode in the first direction is smaller than the dimension of the second electrode in the first direction. The conductive member has a first joining surface to which the first electrode is conductively joined and a second joining surface to which the second electrode is conductively joined. The first joining surface is positioned closer to the element surface than the second joining surface is in the first direction.

### PRIORITY

The present disclosure contains subject matter related to that disclosed in Japanese Priority Patent Application JP 2025-011385 filed in the Japan Patent Office on Jan. 27, 2025, the entire content of which is hereby incorporated by reference.

### BACKGROUND

The present disclosure relates to a semiconductor device.

PCT Patent Publication No. W02021/177034 discloses an example of a semiconductor device provided with a conductive member and a semiconductor element conductively joined to one side of the conductive member in a thickness direction. The semiconductor element has a plurality of electrodes. Each of the plurality of electrodes has a base part and a columnar part projecting from the base part. The columnar part of each of the plurality of electrodes is conductively joined to the conductive member.

In the configuration of the semiconductor device disclosed in PCT Patent Publication No. WO2021/177034, the plurality of electrodes include first electrodes and second electrodes. When viewed in the thickness direction, the area of the columnar part of a second electrode is larger than the area of the columnar part of a first electrode. In this case, if the respective columnar parts of the first electrodes and the second electrodes are integrally formed by electrolytic plating, the dimension of the columnar part of the second electrode in the thickness direction becomes smaller than the dimension of the columnar part of the first electrode in the thickness direction. Accordingly, there is a risk that a joining failure (open failure) with respect to the conductive member occurs in the second electrodes.

### BRIEF DESCRIPTION OF THE DRAWINGS

FIG. 1 is a plan view of a semiconductor device according to a first embodiment of the present disclosure, which is seen through sealing resin;

FIG. 2 is a plan view corresponding to FIG. 1, which is seen further through a first joining layer, a second joining layer, and a semiconductor element;

FIG. 3 is a bottom view of the semiconductor device depicted in FIG. 1;

FIG. 4 is a front view of the semiconductor device depicted in FIG. 1;

FIG. 5 is a right side view of the semiconductor device depicted in FIG. 1;

FIG. 6 is a cross-sectional view taken along line VI-VI of FIG. 2;

FIG. 7 is a cross-sectional view taken along line VII-VII of FIG. 2;

FIG. 8 is a cross-sectional view taken along line VIII-VIII of FIG. 2;

FIG. 9 is a partially enlarged view of FIG. 2 and depicts a vicinity of any one of a plurality of first electrodes of the semiconductor element;

FIG. 10 is a cross-sectional view taken along line X-X of FIG. 9;

FIG. 11 is a partially enlarged view of FIG. 2 and depicts a vicinity of any one of a plurality of second electrodes of the semiconductor element;

FIG. 12 is a cross-sectional view taken along line XII-XII of FIG. 11;

FIG. 13 is a partially enlarged plan view of a semiconductor device according to a second embodiment of the present disclosure and corresponds to FIG. 9;

FIG. 14 is a cross-sectional view taken along line XIV-XIV of FIG. 13;

FIG. 15 is a partially enlarged plan view of a semiconductor device according to a modified example of the second embodiment of the present disclosure and corresponds to FIG. 13;

FIG. 16 is a cross-sectional view taken along line XVI-XVI of FIG. 15;

FIG. 17 is a partially enlarged plan view of a semiconductor device according to a third embodiment of the present disclosure and corresponds to FIG. 9;

FIG. 18 is a cross-sectional view taken along line XVIII-XVIII of FIG. 17;

FIG. 19 is a partially enlarged plan view of a semiconductor device according to a fourth embodiment of the present disclosure and corresponds to FIG. 9;

FIG. 20 is a cross-sectional view taken along line XX-XX of FIG. 19;

FIG. 21 is a plan view of a semiconductor device according to a fifth embodiment of the present disclosure, which is seen through a first joining layer, a second joining layer, a semiconductor element, and sealing resin;

FIG. 22 is a cross-sectional view taken along line XXII-XXII of FIG. 21;

FIG. 23 is a cross-sectional view taken along line XXIII-XXIII of FIG. 21;

FIG. 24 is a partially enlarged view of FIG. 22;

FIG. 25 is a partially enlarged view of FIG. 23.

### DETAILED DESCRIPTION

Details of the present disclosure will be described on the basis of the accompanying drawings.

### First Embodiment

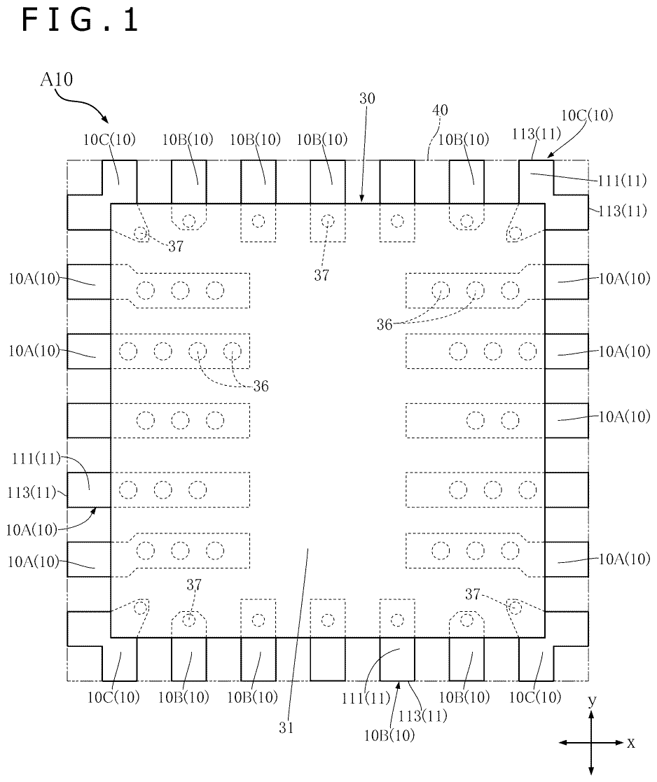

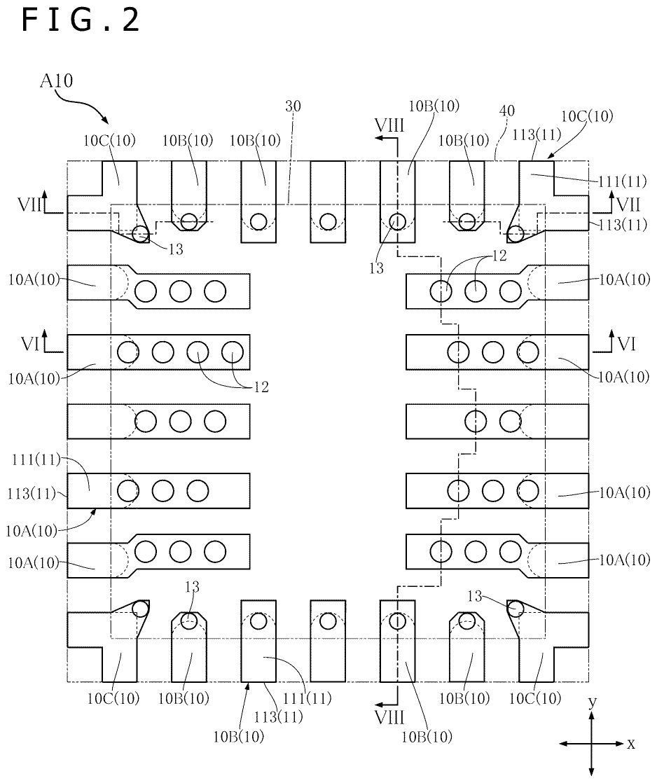

A semiconductor device A10 according to a first embodiment of the present disclosure will be described on the basis of FIG. 1 to FIG. 12. The semiconductor device A10 is provided with a conductive member 10, a first joining layer 21, a second joining layer 22, a semiconductor element 30, and sealing resin 40. The semiconductor device A10 is of a resin package type that is surface-mounted on a wiring substrate. The resin package type is a quad flat non-leaded package (QFN) in which a plurality of leads do not project from the sealing resin 40. Here, FIG. 1 is seen through the sealing resin 40 for convenience of understanding. FIG. 2 is seen, with respect to FIG. 1, further through the first joining layer 21, the second joining layer 22, and the semiconductor element 30 for convenience of understanding. In FIG. 1, the see-through sealing resin 40 is depicted by an imaginary line (two-dot chain line). In FIG. 2, each of the see-through semiconductor element 30 and sealing resin 40 is depicted by an imaginary line. Further, in FIG. 2, each of line VII-VII and line VIII-VIII is depicted by a dashed line.

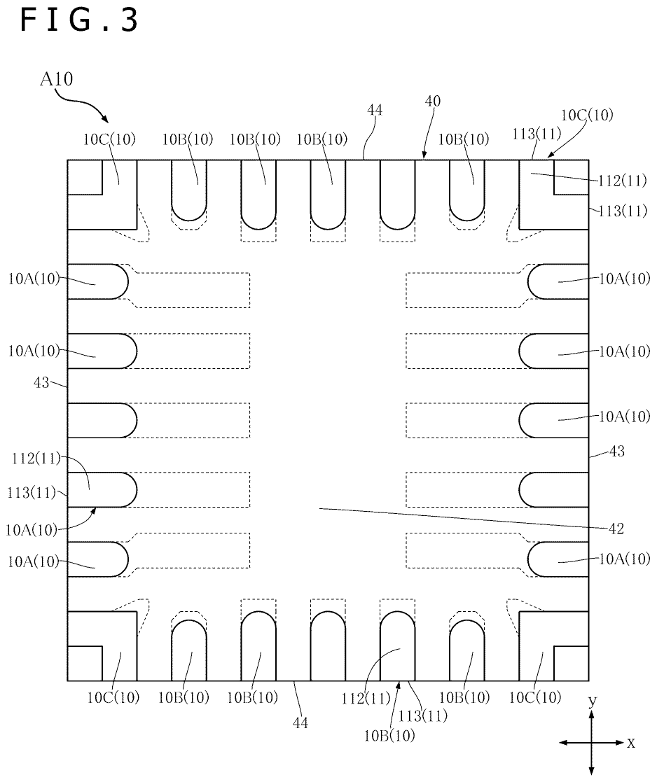

In the description of the semiconductor device A10, a normal direction of a loading surface 111 of a main part 11 to be described later will be referred to as a “first direction z” for convenience. A direction orthogonal to the first direction z will be referred to as a “second direction x.” A direction orthogonal to each of the first direction z and the second direction x will be referred to as a “third direction y.” As depicted in FIG. 3, the semiconductor device A10 has a rectangular shape when viewed in the first direction z.

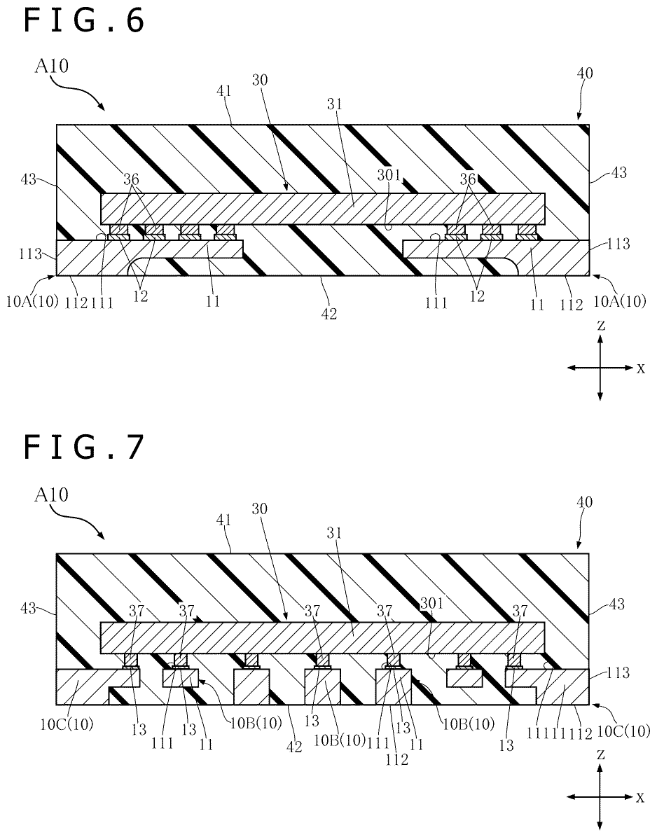

As depicted in FIG. 6 to FIG. 8, the sealing resin 40 covers a part of the conductive member 10 and the semiconductor element 30. The sealing resin 40 has electrical insulation. One example of the material of the sealing resin 40 is black epoxy resin.

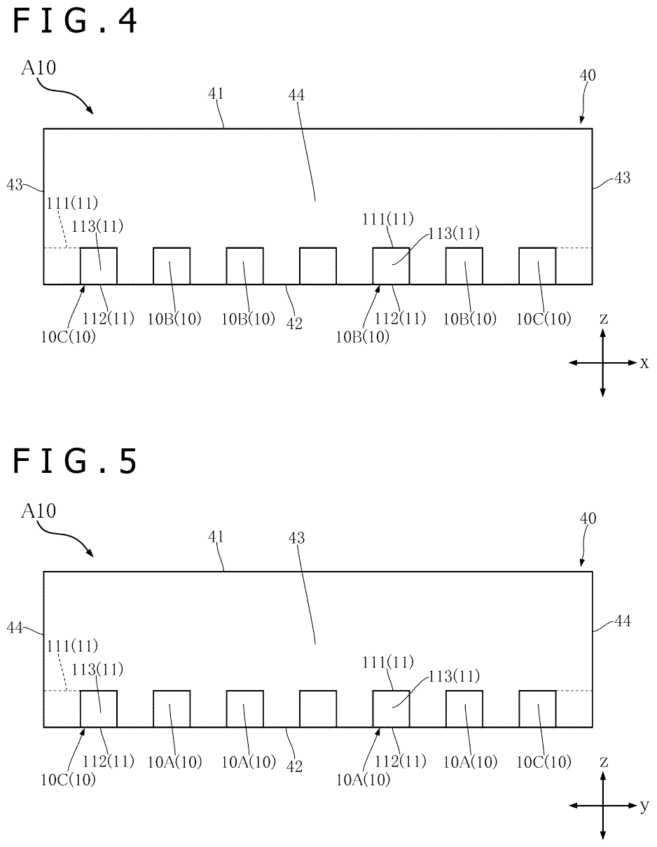

As depicted in FIG. 4 to FIG. 8, the sealing resin 40 has a top surface 41, a bottom surface 42, two first side surfaces 43, and two second side surfaces 44. The top surface 41 and the bottom surface 42 face opposite to each other in the first direction z. Among them, the bottom surface 42 faces opposite to the side where the semiconductor element 30 is positioned with respect to the conductive member 10 in the first direction z. The two first side surfaces 43 face opposite to each other in the second direction x. The two second side surfaces 44 face opposite to each other in the third direction y. The two first side surfaces 43 and the two second side surfaces 44 are positioned between the top surface 41 and the bottom surface 42 in the first direction z.

As depicted in FIG. 6 to FIG. 8, the conductive member 10 has the semiconductor element 30 mounted thereon. The conductive member 10 configures a conductive path between the semiconductor element 30 and the wiring substrate on which the semiconductor device A10 is mounted.

As depicted in FIG. 1 to FIG. 3, the conductive member 10 includes a plurality of first terminals 10A, a plurality of second terminals 10B, and four third terminals 10C. Any one of the plurality of first terminals 10A and any one of the plurality of second terminals 10B are separated from each other in a direction orthogonal to the first direction z. The plurality of first terminals 10A include two terminal groups positioned on both sides of the semiconductor device A10 in the second direction x. Each of the two terminal groups is arranged along the third direction y.

The plurality of second terminals 10B include two terminal groups positioned opposite to each other with the plurality of first terminals 10A interposed therebetween in the third direction y. Each of the two terminal groups is arranged along the second direction x. The dimension of each of the plurality of first terminals 10A in the second direction x is larger than the dimension of each of the plurality of second terminals 10B in the third direction y. When viewed in the first direction z, the four third terminals 10C are arranged at four corners of the semiconductor device A10.

As depicted in FIG. 2, FIG. 3, FIG. 5, FIG. 6, and FIG. 8, each of the plurality of first terminals 10A has a main part 11. The main part 11 of each of the plurality of first terminals 10A contains copper (Cu). Thus, the main part 11 of each of the plurality of first terminals 10A contains metal. The main part 11 of each of the plurality of first terminals 10A is obtained from a lead frame. The main part 11 of each of the plurality of first terminals 10A has the loading surface 111, a mounting surface 112, and an end surface 113. The loading surface 111 faces the same side as the top surface 41 of the sealing resin 40 does in the first direction z. The loading surface 111 is covered with the sealing resin 40. The mounting surface 112 faces opposite to the loading surface 111 in the first direction z. The mounting surface 112 is exposed from the bottom surface 42 of the sealing resin 40. When viewed in the first direction z, the loading surface 111 includes a region overlapping the mounting surface 112 and a region overhung on an outer side than the mounting surface 112. The end surface 113 faces the second direction x. The end surface 113 is exposed from one of the two first side surfaces 43 of the sealing resin 40.

As depicted in FIG. 2, FIG. 6, and FIG. 8, each of the plurality of first terminals 10A has a plurality of first metal layers 12. The plurality of first metal layers 12 are laminated on the loading surface 111 of the main part 11 of any one of the plurality of first terminals 10A. Thus, the plurality of first metal layers 12 are laminated on one side, in the first direction z, of the main part 11 of any one of the plurality of first terminals 10A. Each of the plurality of first metal layers 12 contains, for example, nickel (Ni). In addition, each of the plurality of first metal layers 12 may contain nickel, palladium (Pd), and gold (Au). The metal elements contained in the plurality of first metal layers 12 are different from the metal elements contained in the respective main parts 11 of the plurality of first terminals 10A. The plurality of first metal layers 12 are formed by applying electrolytic plating to the main part 11 of any one of the plurality of first terminals 10A.

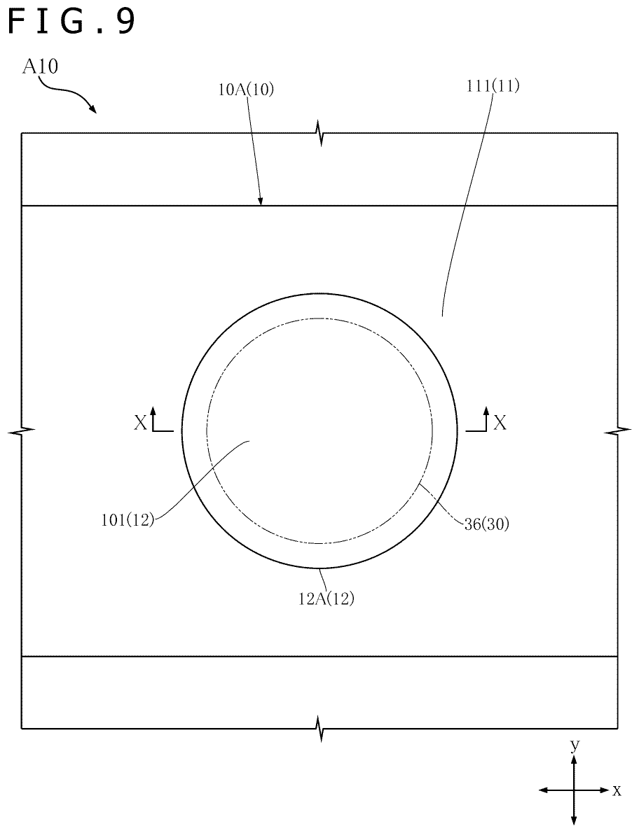

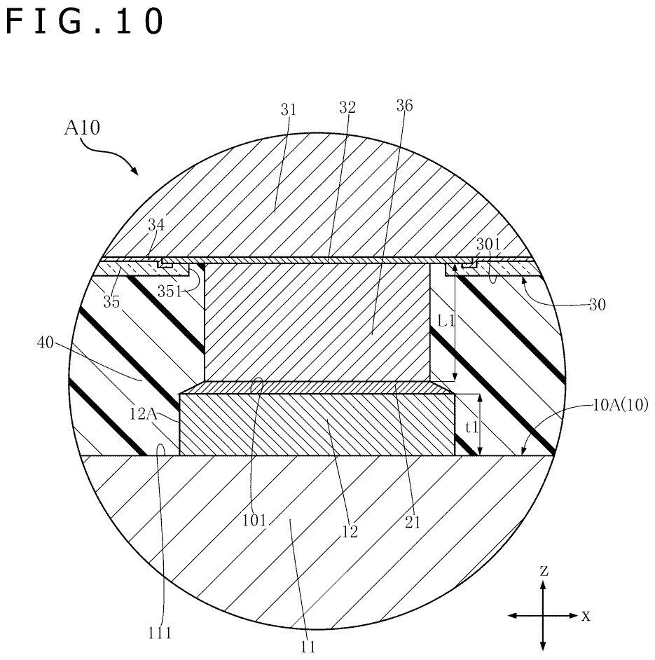

As depicted in FIG. 9 and FIG. 10, each of the plurality of first metal layers 12 has a first joining surface 101 and an end surface 12A. The first joining surface 101 faces the same side as the loading surface 111 of the main part 11 of each of the plurality of first terminals 10A does in the first direction z. Thus, in the semiconductor device A10, the first joining surface 101 is positioned between the main part 11 of any one of the plurality of first terminals 10A and the semiconductor element 30 in the first direction z. The end surface 12A faces a direction orthogonal to the first direction z. When viewed in the first direction z, each of the plurality of first metal layers 12 has a circular shape. However, each of the plurality of first metal layers 12 in plan view can have various shapes such as a rectangular shape in addition to a circular shape.

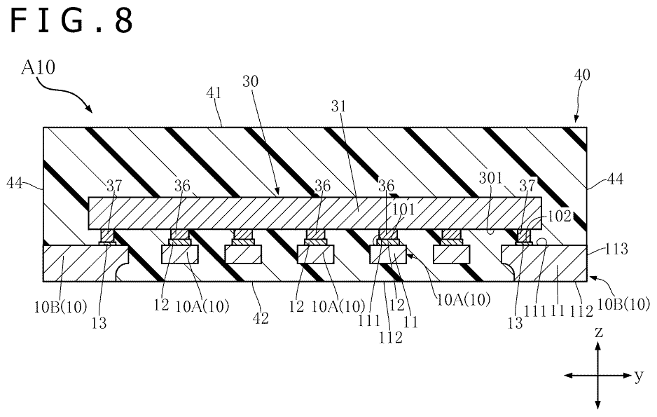

As depicted in FIG. 2 to FIG. 4, FIG. 7, and FIG. 8, each of the plurality of second terminals 10B has a main part 11. The main part 11 of each of the plurality of second terminals 10B contains copper. Thus, the main part 11 of each of the plurality of second terminals 10B contains metal. The main part 11 of each of the plurality of second terminals 10B is obtained from a lead frame.

The main part 11 of each of the plurality of second terminals 10B has a loading surface 111, a mounting surface 112, and an end surface 113. The loading surface 111 faces the same side as the top surface 41 of the sealing resin 40 does in the first direction z. The loading surface 111 is covered with the sealing resin 40. The mounting surface 112 faces opposite to the loading surface 111 in the first direction z. The mounting surface 112 is exposed from the bottom surface 42 of the sealing resin 40. When viewed in the first direction z, the loading surface 111 includes a region overlapping the mounting surface 112 and a region overhung on an outer side than the mounting surface 112. The end surface 113 faces the third direction y. The end surface 113 is exposed from one of the two second side surfaces 44 of the sealing resin 40.

As depicted in FIG. 2, FIG. 7, and FIG. 8, each of the plurality of second terminals 10B has a second metal layer 13. The second metal layer 13 is laminated on the loading surface 111 of the main part 11 of any one of the plurality of second terminals 10B. Thus, the second metal layer 13 is laminated on one side, in the first direction z, of the main part 11 of any one of the plurality of second terminals 10B. Further, the second metal layer 13 is separated from the plurality of first metal layers 12 of each of the plurality of first terminals 10A. The second metal layer 13 contains, for example, nickel. In addition, the second metal layer 13 may contain nickel, palladium, and gold. The metal elements contained in the second metal layer 13 are different from the metal elements contained in the respective main parts 11 of the plurality of second terminals 10B. Further, the metal elements contained in the second metal layer 13 are the same as the metal elements contained in the plurality of first metal layers 12 of each of the plurality of first terminals 10A. The second metal layer 13 is formed by applying electrolytic plating to the main part 11 of any one of the plurality of second terminals 10B.

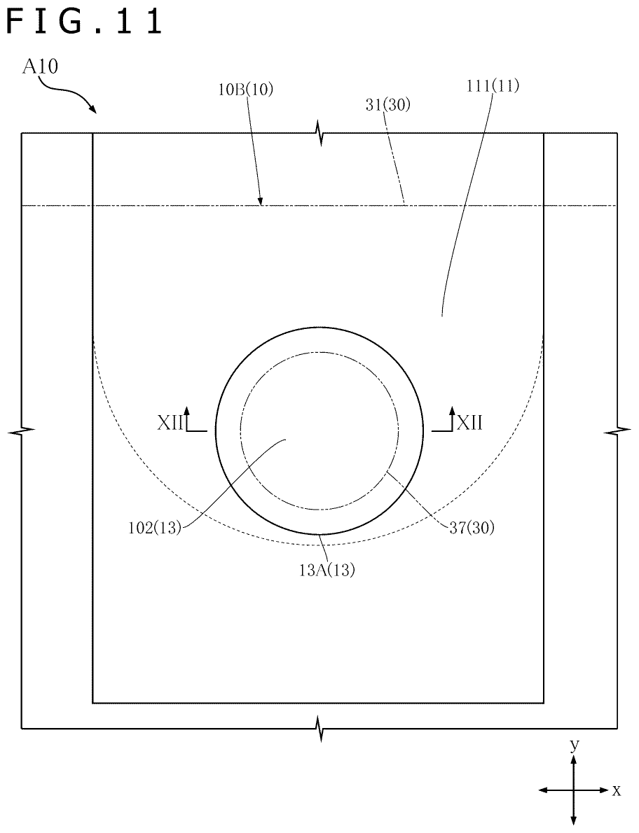

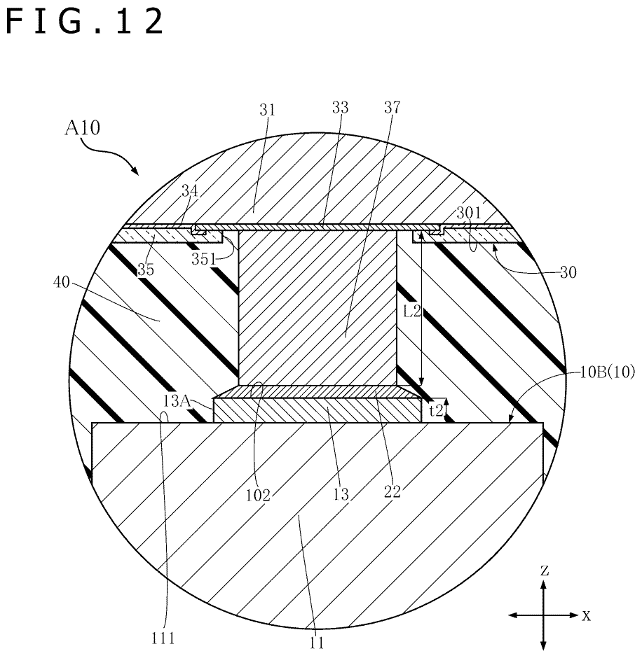

As depicted in FIG. 11 and FIG. 12, the second metal layer 13 has a second joining surface 102 and an end surface 13A. The second joining surface 102 faces the same side as the loading surface 111 of the main part 11 of each of the plurality of second terminals 10B does in the first direction z. Thus, in the semiconductor device A10, the second joining surface 102 is positioned between the main part 11 of any one of the plurality of second terminals 10B and the semiconductor element 30 in the first direction z. The end surface 13A faces a direction orthogonal to the first direction z. When viewed in the first direction z, the second metal layer 13 has a circular shape. However, the second metal layer 13 in plan view can have various shapes such as a rectangular shape in addition to a circular shape.

As depicted in FIG. 10 and FIG. 12, the dimension t1 of each of the plurality of first metal layers 12 in the first direction z is larger than the dimension t2 of the second metal layer 13 in the first direction z.

As depicted in FIG. 2 to FIG. 5 and FIG. 7, each of the four third terminals 10C has a main part 11. The main part 11 of each of the four third terminals 10C contains copper. Thus, the main part 11 of each of the four third terminals 10C contains metal. The main part 11 of each of the four third terminals 10C is obtained from a lead frame. The main part 11 of each of the four third terminals 10C has a loading surface 111, a mounting surface 112, and two end surfaces 113. The loading surface 111 faces the same side as the top surface 41 of the sealing resin 40 does in the first direction z. The loading surface 111 is covered with the sealing resin 40. The mounting surface 112 faces opposite to the loading surface 111 in the first direction z. The mounting surface 112 is exposed from the bottom surface 42 of the sealing resin 40. One of the two end surfaces 113 faces the second direction x and is exposed from one of the two first side surfaces 43. The other of the two end surfaces 113 faces the third direction y and is exposed from one of the two second side surfaces 44.

As depicted in FIG. 2 and FIG. 7, each of the four third terminals 10C has a second metal layer 13. The second metal layer 13 is laminated on the loading surface 111 of the main part 11 of each of the four third terminals 10C. The configuration of the second metal layer 13 is similar to the configuration of the second metal layer 13 of each of the plurality of second terminals 10B described above.

As depicted in FIG. 6 to FIG. 8, the semiconductor element 30 is conductively joined to the conductive member 10 by flip-chip joint. Accordingly, the semiconductor element 30 is conductive to the conductive member 10. As depicted in FIG. 6 to FIG. 8, FIG. 10, and FIG. 12, the semiconductor element 30 has an element surface 301, a main body 31, a plurality of first pads 32, a plurality of second pads 33, a passivation film 34, a protective film 35, a plurality of first electrodes 36, and a plurality of second electrodes 37.

As depicted in FIG. 6 to FIG. 8, the element surface 301 faces the conductive member 10. As depicted in FIG. 10 and FIG. 12, the element surface 301 is included in the protective film 35.

The main body 31 forms a principal part of the semiconductor element 30. The main body 31 includes a semiconductor substrate and a semiconductor layer laminated on the semiconductor substrate. The semiconductor substrate contains, for example, silicon (Si). The semiconductor layer is positioned between the conductive member 10 and the semiconductor substrate in the first direction z.

The plurality of first pads 32 are individually and electrically connected to the plurality of first electrodes 36. As depicted in FIG. 10, the plurality of first pads 32 are in contact with the main body 31. The plurality of first pads 32 are conductive to the main body 31.

The plurality of second pads 33 are individually and electrically connected to the plurality of second electrodes 37. As depicted in FIG. 12, the plurality of second pads 33 are in contact with the main body 31. The plurality of second pads 33 are conductive to the main body 31.

As depicted in FIG. 10 and FIG. 12, the passivation film 34 is positioned between the main body 31 and the conductive member 10 in the first direction z and is laminated on the main body 31. The passivation film 34 has electrical insulation. The passivation film 34 contains, for example, at least one of silicon oxide (SiO₂) and silicon nitride (Si₃N₄). The passivation film 34 covers a part of each of the plurality of first pads 32 and a part of each of the plurality of second pads 33.

As depicted in FIG. 10 and FIG. 12, the protective film 35 is positioned between the passivation film 34 and the conductive member 10 in the first direction z and is laminated on the passivation film 34. The protective film 35 has electrical insulation. The protective film 35 contains, for example, polyimide. The protective film 35 is provided with a plurality of openings 351 penetrating therethrough in the first direction z. Any one of the plurality of first pads 32 or any one of the plurality of second pads 33 is exposed from each of the plurality of openings 351.

As depicted in FIG. 6 and FIG. 8, the plurality of first electrodes 36 project from the element surface 301 of the semiconductor element 30 toward the conductive member 10. Each of the plurality of first electrodes 36 is conductive to the main body 31 via any one of the plurality of first pads 32. As depicted in FIG. 9, each of the plurality of first electrodes 36 has a columnar shape when viewed in the first direction z. However, each of the plurality of first electrodes 36 in plan view can have various shapes such as a rectangular shape in addition to a circular shape. The plurality of first electrodes 36 contain, for example, copper. As depicted in FIG. 10, each of the plurality of first electrodes 36 is conductively joined to any one of the plurality of first metal layers 12 of each of the plurality of first terminals 10A. A part of each of the plurality of first electrodes 36 is individually housed in the corresponding one of the plurality of openings 351 of the protective film 35.

As depicted in FIG. 10, the first joining layer 21 conductively joins the first joining surface 101 of any one of the plurality of first metal layers 12 of each of the plurality of first terminals 10A to any one of the plurality of first electrodes 36 facing the first joining surface 101. The first joining layer 21 contains metal elements. The first joining layer 21 contains, for example, tin (Sn) and silver (Ag). In addition, the first joining layer 21 may contain tin and antimony (Sb) or may be a sintered body of metal particles. The metal particles contain, for example, silver. In any one of the plurality of first metal layers 12 of each of the plurality of first terminals 10A, the end surface 12A of the first metal layer 12 is exposed from the first joining layer 21.

As depicted in FIG. 7 and FIG. 8, the plurality of second electrodes 37 project from the element surface 301 of the semiconductor element 30 toward the conductive member 10. Each of the plurality of second electrodes 37 is conductive to the main body 31 via any one of the plurality of second pads 33. As depicted in FIG. 11, each of the plurality of second electrodes 37 has a columnar shape when viewed in the first direction z. However, each of the plurality of second electrodes 37 in plan view can have various shapes such as a rectangular shape in addition to a circular shape. The plurality of second electrodes 37 contain, for example, copper. As depicted in FIG. 12, each of the plurality of second electrodes 37 is conductively joined to any one of the second metal layer 13 of each of the plurality of second terminals 10B and the second metal layer 13 of each of the four third terminals 10C. A part of each of the plurality of second electrodes 37 is individually housed in the corresponding one of the plurality of openings 351 of the protective film 35.

As depicted in FIG. 12, the second joining layer 22 conductively joins the second joining surface 102 of the second metal layer 13 of each of the plurality of second terminals 10B to any one of the plurality of second electrodes 37 facing the second joining surface 102. The second joining layer 22 contains metal elements. The metal elements contained in the second joining layer 22 are the same as the metal elements contained in the first joining layer 21. In the second metal layer 13 of any one of the plurality of second terminals 10B, the end surface 13A of the second metal layer 13 is exposed from the second joining layer 22.

As depicted in FIG. 9 and FIG. 11, the area of each of the plurality of first electrodes 36 is larger than the area of each of the plurality of second electrodes 37 when viewed in the first direction z. As depicted in FIG. 10 and FIG. 12, the dimension L1 of each of the plurality of first electrodes 36 in the first direction z is smaller than the dimension L2 of each of the plurality of second electrodes 37 in the first direction z.

As depicted in FIG. 10 and FIG. 12, in the first direction z, the first joining surface 101 of any one of the plurality of first metal layers 12 of each of the plurality of first terminals 10A is positioned closer to the element surface 301 of the semiconductor element 30 than the second joining surface 102 of the second metal layer 13 of any one of the plurality of second terminals 10B is.

Next, working effects of the semiconductor device A10 will be described.

The semiconductor device A10 is provided with the conductive member 10 and the semiconductor element 30 positioned on one side of the conductive member 10 in the first direction z. The semiconductor element 30 has the element surface 301, the first electrodes 36, and the second electrodes 37. When viewed in the first direction z, the area of the first electrode 36 is larger than the area of the second electrode 37. The dimension L1 of the first electrode 36 in the first direction z is smaller than the dimension L2 of the second electrode 37 in the first direction z. The conductive member 10 has the first joining surface 101 to which the first electrode 36 is conductively joined and the second joining surface 102 to which the second electrode 37 is conductively joined. In the first direction z, the first joining surface 101 is positioned closer to the element surface 301 than the second joining surface 102 is. With this configuration, a difference between the distance from the first joining surface 101 to the element surface 301 in the first direction z and the distance from the second joining surface 102 to the element surface 301 in the first direction z can be made smaller. Accordingly, when the semiconductor element 30 is conductively joined to the conductive member 10, a gap between the first joining surface 101 and the first electrode 36 can be prevented from being excessively larger than a gap between the second joining surface 102 and the second electrode 37. Further, when the semiconductor element 30 is conductively joined to the conductive member 10, an inclination of the semiconductor element 30 around a direction orthogonal to the first direction z can be suppressed. Thus, according to this configuration, in a configuration in which the semiconductor device A10 is provided with the first electrodes 36 and the second electrodes 37 whose sizes are different from each other, each of the first electrodes 36 and the second electrodes 37 can be conductively joined to the conductive member 10 more firmly.

The conductive member 10 has the main parts 11 containing metal, and the first metal layers 12 and the second metal layers 13 that are laminated on one side of the main parts 11 in the first direction z. The first metal layer 12 includes the first joining surface 101. The second metal layer 13 includes the second joining surface 102. With this configuration, the conductive member 10 having the first joining surfaces 101 and the second joining surfaces 102 can be easily formed by applying electrolytic plating to a lead frame.

The dimension t1 of the first metal layer 12 in the first direction z is larger than the dimension t2 of the second metal layer 13 in the first direction z. With this configuration, even though the loading surface 111 of the main part 11 facing one side in the first direction z is flat, the position of each of the first joining surface 101 and the second joining surface 102 in the first direction z can be set to be a predetermined position.

The semiconductor device A10 is further provided with the first joining layer 21 for conductively joining the first joining surface 101 and the first electrode 36 of the semiconductor element 30 to each other, and the second joining layer 22 for conductively joining the second joining surface 102 and the second electrode 37 of the semiconductor element 30 to each other. The first joining layer 21 and the second joining layer 22 contain the same metal elements. With this configuration, since the materials of the first joining layer 21 and the second joining layer 22 can be made the same, an increase in the manufacturing cost of the semiconductor device A10 can be suppressed.

The semiconductor device A10 is further provided with the sealing resin 40 for covering the semiconductor element 30. The main part 11 of the conductive member 10 has the mounting surface 112 and the end surface 113 each of which is exposed from the sealing resin 40. The end surface 113 faces a direction orthogonal to the first direction z. With this configuration, when the semiconductor device A10 is mounted on the wiring substrate, solder also adheres to the end surface 113. Accordingly, the mounting strength of the semiconductor device A10 to the wiring substrate is improved.

### Second Embodiment

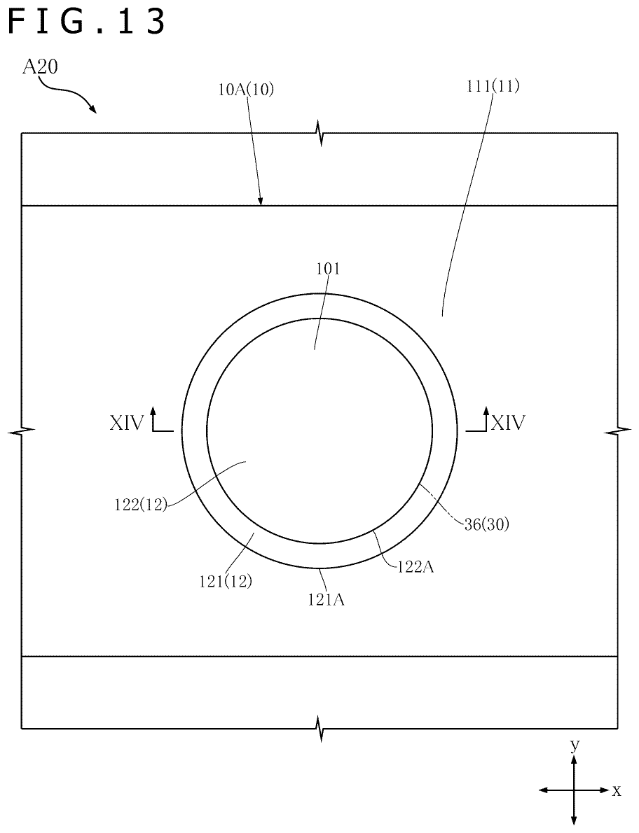

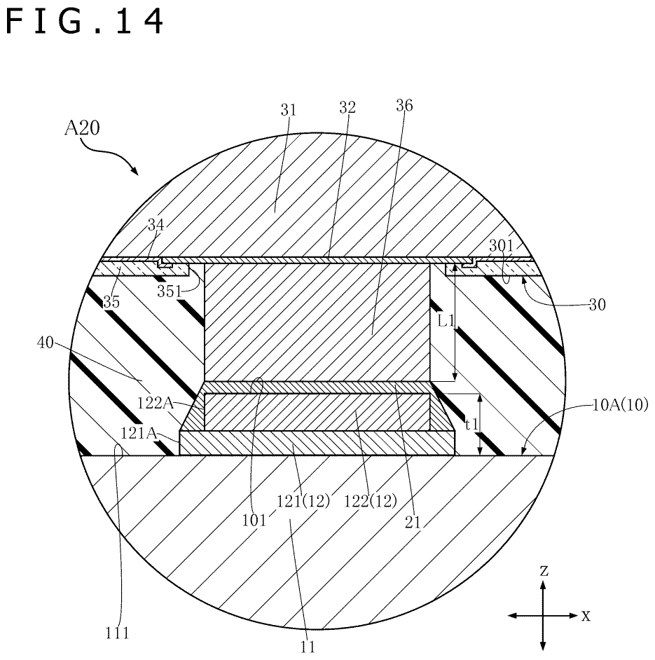

A semiconductor device A20 according to a second embodiment of the present disclosure will be described on the basis of FIG. 13 and FIG. 14. In these drawings, elements same as or similar to those of the above-described semiconductor device A10 are denoted by the same reference symbols, and duplicated descriptions thereof will be omitted. Here, FIG. 13 corresponds to FIG. 9 depicting the semiconductor device A10.

In the semiconductor device A20, the configurations of the plurality of first metal layers 12 of each of the plurality of first terminals 10A are different from those in the semiconductor device A10.

As depicted in FIG. 13 and FIG. 14, each of the plurality of first metal layers 12 has a first layer 121 and a second layer 122. The first layer 121 is laminated on the loading surface 111 of the main part 11 of any one of the plurality of first metal layers 12. The second layer 122 is positioned opposite to the main part 11 of any one of the plurality of first metal layers 12 with the first layer 121 interposed therebetween and is laminated on the first layer 121. The second layer 122 includes the first joining surface 101. The first layer 121 and the second layer 122 contain the same metal elements. Alternatively, the first layer 121 and the second layer 122 may contain metal elements that are different from each other. As an example of this case, the first layer 121 contains nickel, and the second layer 122 contains palladium and gold.

As depicted in FIG. 13 and FIG. 14, the second layer 122 is positioned on an inner side than the first layer 121 when viewed in the first direction z. When viewed in the first direction z, the first layer 121 includes a portion protruding on an outer side than any one of the plurality of first electrodes 36 of the semiconductor element 30 facing the first joining surface 101. When viewed in the first direction z, a peripheral edge of any one of the plurality of first electrodes 36 facing the first joining surface 101 overlaps a peripheral edge of the second layer 122.

As depicted in FIG. 13 and FIG. 14, the first layer 121 has a first end surface 121A facing a direction orthogonal to the first direction z. The first end surface 121A is exposed from the first joining layer 21. The second layer 122 has a second end surface 122A facing a direction orthogonal to the first direction z. The second end surface 122A is covered with the first joining layer 21. As depicted in FIG. 14, the dimension of the second layer 122 in the first direction z is larger than the dimension of the first layer 121 in the first direction z. The dimension of the first layer 121 in the first direction z is equal to the dimension of the second metal layer 13 of any one of the plurality of second terminals 10B in the first direction z.

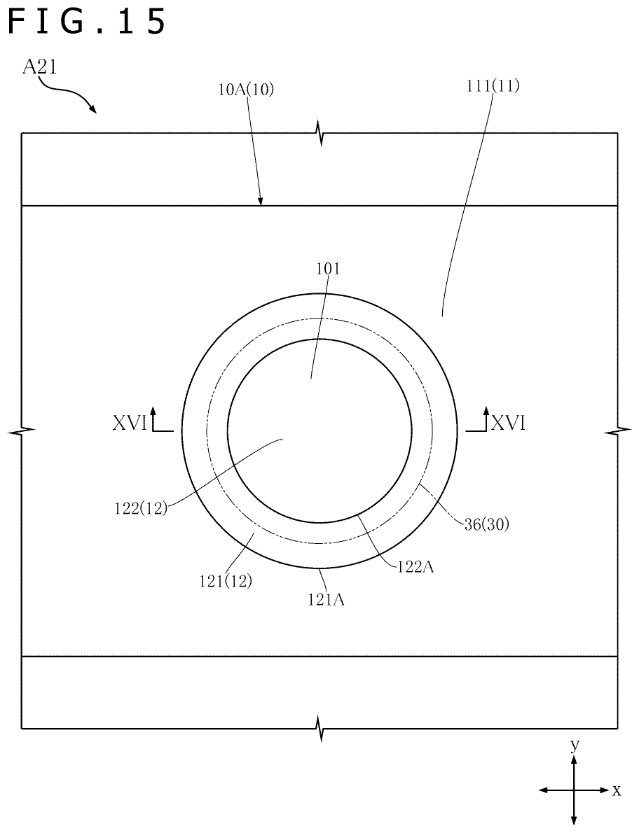

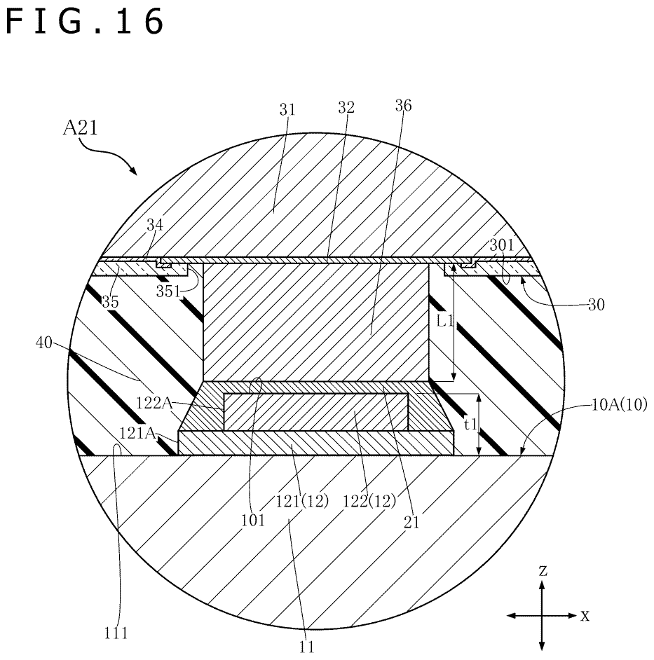

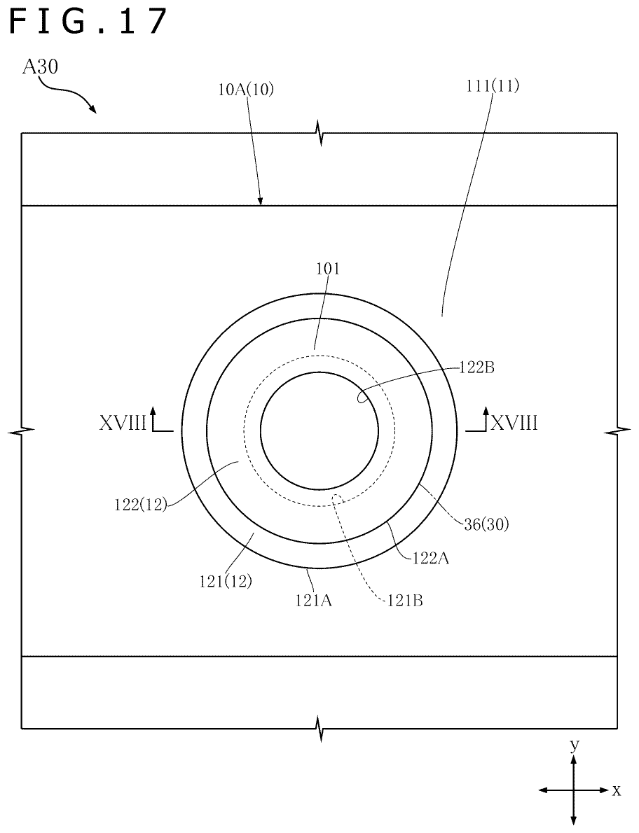

Next, as depicted in FIG. 15 and FIG. 16, a semiconductor device A21 according to a modified example of the second embodiment of the present disclosure will be described. Here, FIG. 15 corresponds to FIG. 13 depicting the semiconductor device A20.

In the semiconductor device A21, the configurations of the plurality of first metal layers 12 of each of the plurality of first terminals 10A are different from those in the semiconductor device A20. As depicted in FIG. 15 and FIG. 16, in any one of the plurality of first metal layers 12 of each of the plurality of first terminals 10A, the second layer 122 is positioned on an inner side than any one of the plurality of first electrodes 36 of the semiconductor element 30 facing the first joining surface 101 when viewed in the first direction z.

Next, working effects of the semiconductor device A20 will be described.

The semiconductor device A20 is provided with the conductive member 10 and the semiconductor element 30 positioned on one side of the conductive member 10 in the first direction z. The semiconductor element 30 has the element surface 301, the first electrodes 36, and the second electrodes 37. When viewed in the first direction z, the area of the first electrode 36 is larger than the area of the second electrode 37. The dimension Ll of the first electrode 36 in the first direction z is smaller than the dimension L2 of the second electrode 37 in the first direction z. The conductive member 10 has the first joining surface 101 to which the first electrode 36 is conductively joined and the second joining surface 102 to which the second electrode 37 is conductively joined. In the first direction z, the first joining surface 101 is positioned closer to the element surface 301 than the second joining surface 102 is. Thus, according to this configuration, in a configuration in which the semiconductor device A20 is provided with the first electrodes 36 and the second electrodes 37 whose sizes are different from each other, each of the first electrodes 36 and the second electrodes 37 can be conductively joined to the conductive member 10 more firmly. Further, the semiconductor device A20 is provided with a configuration same as that of the semiconductor device A10, so that working effects equivalent to those of the semiconductor device A10 can be exhibited.

In the semiconductor device A20, the first metal layer 12 of the conductive member 10 has the first layer 121 and the second layer 122. The second layer 122 includes the first joining surface 101 of the conductive member 10. With this configuration, when forming the first metal layer 12, the first layer 121 and the second layer 122 are formed in separate steps. Accordingly, the position of the first joining surface 101 in the first direction z can be more accurately set.

When viewed in the first direction z, the second layer 122 of the first metal layer 12 is positioned on the inner side than the first layer 121 of the first metal layer 12. When viewed in the first direction z, the first layer 121 includes a portion protruding on the outer side than the first electrode 36 of the semiconductor element 30. With this configuration, the surface area of the first metal layer 12 to which the first joining layer 21 adheres is further enlarged, so that the joining strength of the first electrode 36 of the semiconductor element 30 to the conductive member 10 is improved.

The first layer 121 of the first metal layer 12 has the first end surface 121A exposed from the first joining layer 21. The second layer 122 of the first metal layer 12 has the second end surface 122A covered with the first joining layer 21. With this configuration, force by which the first joining layer 21 is leaked on the outer side than the first layer 121 when viewed in the first direction z is effectively reduced by surface tension of the first joining layer 21 with respect to the first metal layer 12. Accordingly, the joining strength of the first electrode 36 of the semiconductor element 30 to the first metal layer 12 can be improved while a joining failure of the first electrode 36 to the first metal layer 12 is effectively prevented.

### Third Embodiment

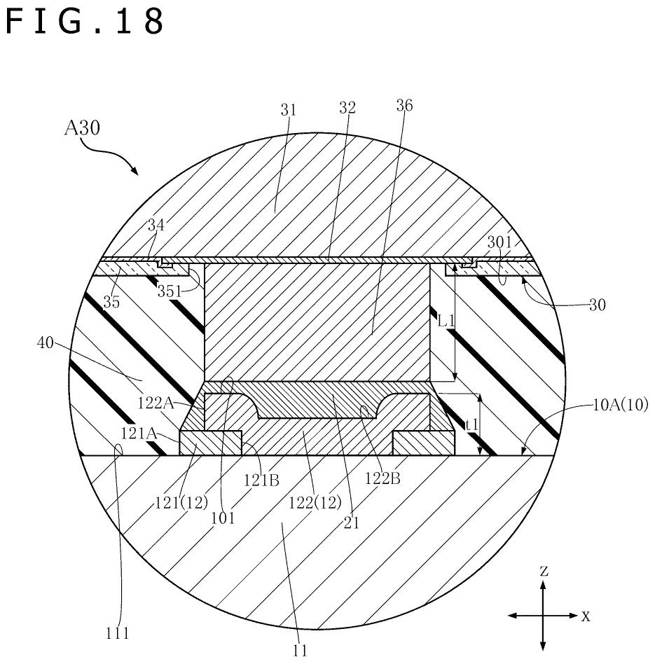

A semiconductor device A30 according to a third embodiment of the present disclosure will be described on the basis of FIG. 17 and FIG. 18. In these drawings, elements same as or similar to those of the above-described semiconductor device A10 and semiconductor device A20 are denoted by the same reference symbols, and duplicated descriptions thereof will be omitted. Here, FIG. 17 corresponds to FIG. 9 depicting the semiconductor device A10.

In the semiconductor device A30, the configurations of the plurality of first metal layers 12 of each of the plurality of first terminals 10A are different from those in the semiconductor device A20.

As depicted in FIG. 17 and FIG. 18, each of the plurality of first metal layers 12 has the first layer 121 and the second layer 122. The first layer 121 has a first opening 121B penetrating therethrough in the first direction z. The loading surface 111 of the main part 11 of any one of the plurality of first terminals 10A is exposed from the first opening 121B. The second layer 122 has a second opening 122B opening from the first joining surface 101. The second opening 122B is recessed from the first joining surface 101. When viewed in the first direction z, the second opening 122B overlaps the first opening 121B. The second layer 122 includes a portion housed in the first opening 121B. The portion is in contact with the first joining surface 101. A part of the first joining layer 21 is housed in the second opening 122B.

Next, working effects of the semiconductor device A30 will be described.

The semiconductor device A30 is provided with the conductive member 10 and the semiconductor element 30 positioned on one side of the conductive member 10 in the first direction z. The semiconductor element 30 has the element surface 301, the first electrodes 36, and the second electrodes 37. When viewed in the first direction z, the area of the first electrode 36 is larger than the area of the second electrode 37. The dimension L1 of the first electrode 36 in the first direction z is smaller than the dimension L2 of the second electrode 37 in the first direction z. The conductive member 10 has the first joining surface 101 to which the first electrode 36 is conductively joined and the second joining surface 102 to which the second electrode 37 is conductively joined. In the first direction z, the first joining surface 101 is positioned closer to the element surface 301 than the second joining surface 102 is. Thus, according to this configuration, in a configuration in which the semiconductor device A30 is provided with the first electrodes 36 and the second electrodes 37 whose sizes are different from each other, each of the first electrodes 36 and the second electrodes 37 can be conductively joined to the conductive member 10 more firmly. Further, the semiconductor device A30 is provided with a configuration same as that of the semiconductor device A10, so that working effects equivalent to those of the semiconductor device A10 can be exhibited.

In the semiconductor device A30, the first metal layer 12 of the conductive member 10 has the first layer 121 and the second layer 122. The second layer 122 has the second opening 122B opening from the first joining surface 101. A part of the first joining layer 21 is housed in the second opening 122B. With this configuration, an anchor effect with respect to the first metal layer 12 is exhibited in the first joining layer 21. Accordingly, the joining strength of the first electrode 36 of the semiconductor element 30 to the conductive member 10 is further improved.

### Fourth Embodiment

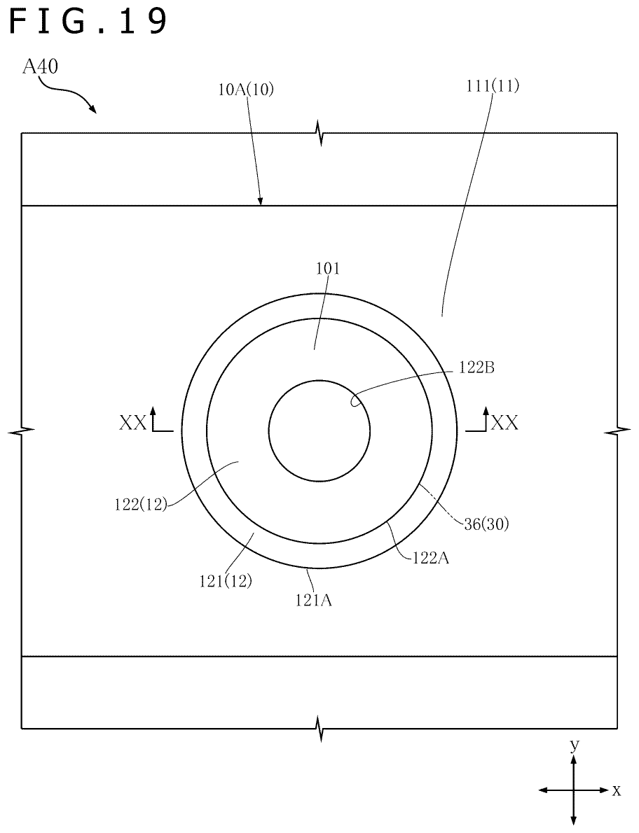

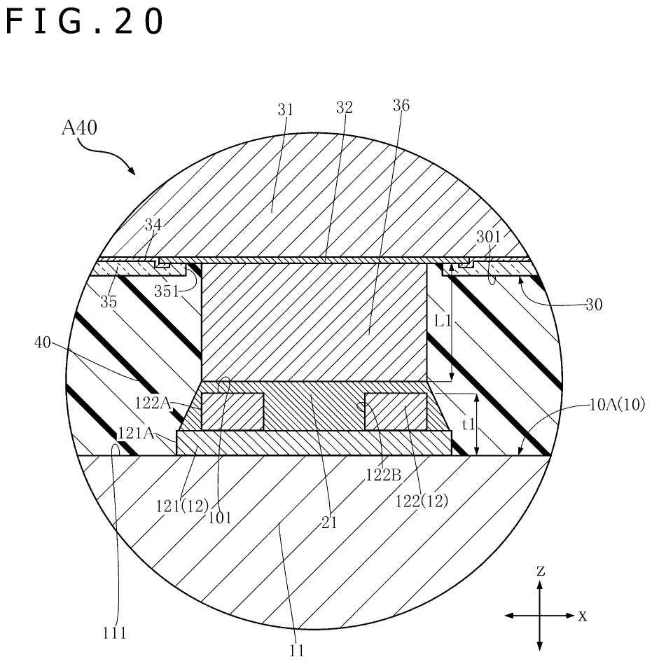

A semiconductor device A40 according to a fourth embodiment of the present disclosure will be described on the basis of FIG. 19 and FIG. 20. In these drawings, elements same as or similar to those of the above-described semiconductor device A10 and semiconductor device A20 are denoted by the same reference symbols, and duplicated descriptions thereof will be omitted. Here, FIG. 19 corresponds to FIG. 9 depicting the semiconductor device A10.

In the semiconductor device A40, the configurations of the plurality of first metal layers 12 of each of the plurality of first terminals 10A are different from those in the semiconductor device A20.

As depicted in FIG. 19 and FIG. 20, each of the plurality of first metal layers 12 has the first layer 121 and the second layer 122. The second layer 122 has the second opening 122B opening from the first joining surface 101. The second opening 122B penetrates the second layer 122 in the first direction z. The first layer 121 is exposed from the second opening 122B. A part of the first joining layer 21 is housed in the second opening 122B and is in contact with a portion of the first layer 121 exposed from the second opening 122B.

Next, working effects of the semiconductor device A40 will be described.

The semiconductor device A40 is provided with the conductive member 10 and the semiconductor element 30 positioned on one side of the conductive member 10 in the first direction z. The semiconductor element 30 has the element surface 301, the first electrodes 36, and the second electrodes 37. When viewed in the first direction z, the area of the first electrode 36 is larger than the area of the second electrode 37. The dimension L1 of the first electrode 36 in the first direction z is smaller than the dimension L2 of the second electrode 37 in the first direction z. The conductive member 10 has the first joining surface 101 to which the first electrode 36 is conductively joined and the second joining surface 102 to which the second electrode 37 is conductively joined. In the first direction z, the first joining surface 101 is positioned closer to the element surface 301 than the second joining surface 102 is. Thus, according to this configuration, in a configuration in which the semiconductor device A40 is provided with the first electrodes 36 and the second electrodes 37 whose sizes are different from each other, each of the first electrodes 36 and the second electrodes 37 can be conductively joined to the conductive member 10 more firmly. Further, the semiconductor device A40 is provided with a configuration same as that of the semiconductor device A10, so that working effects equivalent to those of the semiconductor device A10 can be exhibited.

In the semiconductor device A40, the first metal layer 12 of the conductive member 10 has the first layer 121 and the second layer 122. The second layer 122 has the second opening 122B opening from the first joining surface 101. A part of the first joining layer 21 is housed in the second opening 122B. With this configuration, an anchor effect with respect to the first metal layer 12 is exhibited in the first joining layer 21 even in the semiconductor device A40, so that the joining strength of the first electrode 36 of the semiconductor element 30 to the conductive member 10 is further improved.

In the first metal layer 12 of the semiconductor device A40, the first joining layer 21 is in contact with a portion of the first layer 121 exposed from the second opening 122B of the second layer 122. With this configuration, the surface area of the first metal layer 12 to which the first joining layer 21 adheres is further enlarged, so that the joining strength of the first electrode 36 of the semiconductor element 30 to the conductive member 10 can be effectively improved.

### Fifth Embodiment

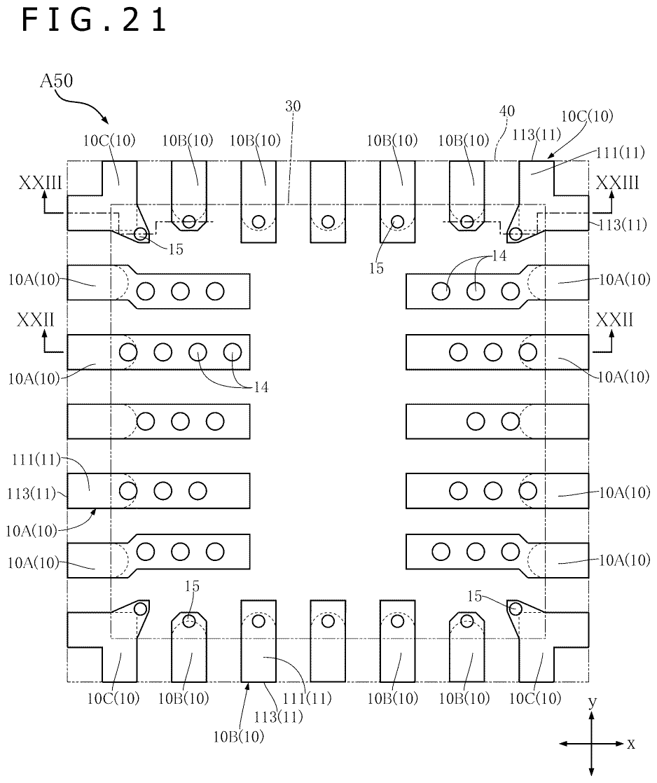

A semiconductor device A50 according to a fifth embodiment of the present disclosure will be described on the basis of FIG. 21 to FIG. 25. In these drawings, elements same as or similar to those of the above-described semiconductor device A10 and semiconductor device A20 are denoted by the same reference symbols, and duplicated descriptions thereof will be omitted. Here, FIG. 21 is seen through the first joining layer 21, the second joining layer 22, the semiconductor element 30, and the sealing resin 40 for convenience of understanding. In FIG. 21, each of the see-through semiconductor element 30 and sealing resin 40 is depicted by an imaginary line. Further, in FIG. 21, each line XXIII-XXIII is depicted by a dashed line.

In the semiconductor device A50, the configuration of the conductive member 10 is different from that in the semiconductor device A10.

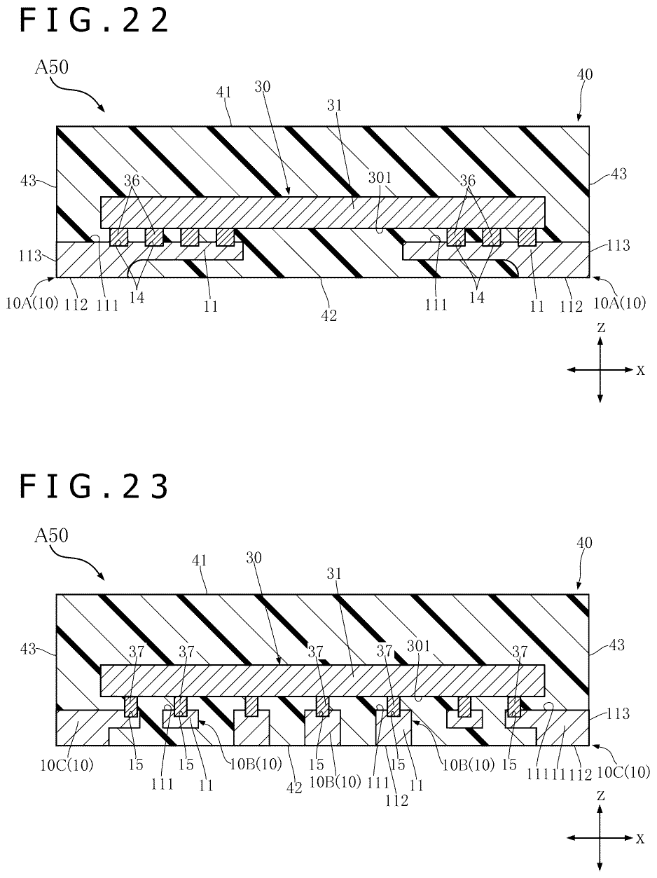

As depicted in FIG. 21 and FIG. 22, each of the plurality of first terminals 10A has a plurality of first recessed parts 14 in place of the plurality of first metal layers 12. Each of the plurality of first recessed parts 14 is recessed from the loading surface 111 of the main part 11 of any one of the plurality of first terminals 10A. The first joining surface 101 of the conductive member 10 defines any one of the plurality of first recessed parts 14.

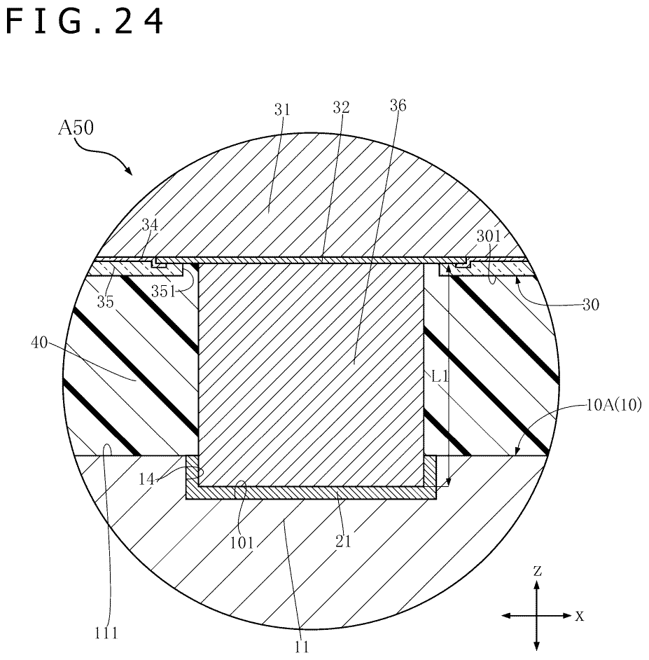

As depicted in FIG. 22 and FIG. 24, a part of any one of the plurality of first electrodes 36 of the semiconductor element 30 is housed in any one of the plurality of first recessed parts 14 of each of the plurality of first terminals 10A. The first joining layer 21 is housed in any one of the plurality of first recessed parts 14. Accordingly, any one of the plurality of first electrodes 36 faces the first joining surface 101 and is conductively joined to the first joining surface 101 via the first joining layer 21.

As depicted in FIG. 21 and FIG. 23, each of the plurality of second terminals 10B and the four third terminals 10C has a second recessed part 15 in place of the second metal layer 13. The second recessed part 15 is recessed from the loading surface 111 of the main part 11 of any one of the plurality of second terminals 10B or any one of the four third terminals 10C. The second joining surface 102 of the conductive member 10 defines the second recessed part 15.

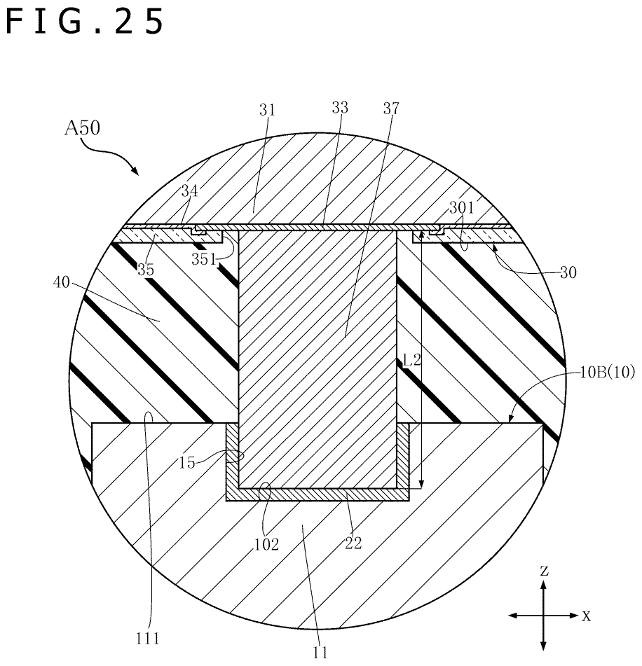

As depicted in FIG. 23 and FIG. 25, a part of any one of the plurality of second electrodes 37 of the semiconductor element 30 is housed in the second recessed part 15 of any one of the plurality of second terminals 10B or any one of the four third terminals 10C. The second joining layer 22 is housed in the second recessed part 15. Accordingly, any one of the plurality of second electrodes 37 faces the second joining surface 102 and is conductively joined to the second joining surface 102 via the second joining layer 22.

As depicted in FIG. 24 and FIG. 25, in the first direction z, the dimension of any one of the plurality of first recessed parts 14 of each of the plurality of first terminals 10A in the first direction z is smaller than the dimension of the second recessed part 15 of any one of the plurality of second terminals 10B in the first direction z. Accordingly, even in the semiconductor device A50, the first joining surface 101 of any one of the plurality of first terminals 10A is positioned closer to the element surface 301 of the semiconductor element 30 than the second joining surface 102 of any one of the plurality of second terminals 10B is in the first direction z.

Next, working effects of the semiconductor device A50 will be described.

The semiconductor device A50 is provided with the conductive member 10 and the semiconductor element 30 positioned on one side of the conductive member 10 in the first direction z. The semiconductor element 30 has the element surface 301, the first electrodes 36, and the second electrodes 37. When viewed in the first direction z, the area of the first electrode 36 is larger than the area of the second electrode 37. The dimension L1 of the first electrode 36 in the first direction z is smaller than the dimension L2 of the second electrode 37 in the first direction z. The conductive member 10 has the first joining surface 101 to which the first electrode 36 is conductively joined and the second joining surface 102 to which the second electrode 37 is conductively joined. In the first direction z, the first joining surface 101 is positioned closer to the element surface 301 than the second joining surface 102 is. Thus, according to this configuration, in a configuration in which the semiconductor device A50 is provided with the first electrodes 36 and the second electrodes 37 whose sizes are different from each other, each of the first electrodes 36 and the second electrodes 37 can be conductively joined to the conductive member 10 more firmly. Further, the semiconductor device A50 is provided with a configuration same as that of the semiconductor device A10, so that working effects equivalent to those of the semiconductor device A10 can be exhibited.

The present disclosure is not limited to the above-described embodiments. The specific configuration of each part of the present disclosure can be changed in various designs.

The present disclosure includes embodiments described in the following supplementary notes.

### Supplementary Note 1

A semiconductor device (A10) including:
a conductive member (10); and
a semiconductor element (30) that is positioned on one side of the conductive member in a first direction (z) and is conductive to the conductive member,
in which the semiconductor element has an element surface (301) facing the conductive member, and a first electrode (36) and a second electrode (37) that are projecting from the element surface,
an area of the first electrode is larger than an area of the second electrode when viewed in the first direction,
a dimension (L1) of the first electrode in the first direction is smaller than a dimension (L2) of the second electrode in the first direction,
the conductive member has a first joining surface (101) to which the first electrode is conductively joined and a second joining surface (102) to which the second electrode is conductively joined, and
the first joining surface is positioned closer to the element surface than the second joining surface is in the first direction.

### Supplementary Note 2

The semiconductor device (A10) according to supplementary note 1,
in which the conductive member (10) has a main part (11) containing metal, and a first metal layer (12) and a second metal layer (13) that are laminated on one side of the main part in the first direction (z),
the first metal layer includes the first joining surface (101), and
the second metal layer includes the second joining surface (102).

### Supplementary Note 3

The semiconductor device (A10) according to supplementary note 2,
in which a dimension (t1) of the first metal layer (12) in the first direction is larger than a dimension (t2) of the second metal layer (13) in the first direction.

### Supplementary Note 4

The semiconductor device (A10) according to supplementary note 3, further including:
a first joining layer (21) for conductively joining the first joining surface (101) and the first electrode (36) to each other; and
a second joining layer (22) for conductively joining the second joining surface (102) and the second electrode (37) to each other,
in which the first joining layer and the second joining layer contain the same metal elements.

### Supplementary Note 5

The semiconductor device (A20) according to supplementary note 4,
in which the first metal layer (12) has a first layer (121) laminated on the main part (11) and a second layer (122) that is positioned opposite to the main part with the first layer interposed therebetween and is laminated on the first layer, and
the second layer includes the first joining surface (101).

### Supplementary Note 6

The semiconductor device (A20) according to supplementary note 5,
in which the second layer (122) is positioned on an inner side than the first layer (121) when viewed in the first direction (z).

### Supplementary Note 7

The semiconductor device (A20) according to supplementary note 6,
in which a dimension of the second layer (122) in the first direction (z) is larger than a dimension of the first layer (121) in the first direction.

### Supplementary Note 8

The semiconductor device (A20) according to supplementary note 6,
in which the first layer (121) includes a portion protruding on an outer side than the first electrode (36) when viewed in the first direction (z).

### Supplementary Note 9

The semiconductor device (A20) according to supplementary note 8,
in which a peripheral edge of the first electrode (36) overlaps a peripheral edge of the second layer (122) when viewed in the first direction (z).

### Supplementary Note 10

The semiconductor device (A21) according to supplementary note 8,
in which the second layer (122) is positioned on an inner side than the first electrode (36) when viewed in the first direction (z).

### Supplementary Note 11

The semiconductor device (A20) according to supplementary note 8,
in which the second layer (122) has a second end surface (122A) facing a direction orthogonal to the first direction (z), and
the second end surface is covered with the first joining layer (21).

### Supplementary Note 12

The semiconductor device (A20) according to supplementary note 11,
in which the first layer (121) has a first end surface (121A) facing a direction orthogonal to the first
the first end surface is exposed from the first joining layer (21).

### Supplementary Note 13

The semiconductor device (A30, A40) according to supplementary note 11,
in which the second layer (122) has a second opening (122B) opening from the first joining surface (101), and
a part of the first joining layer (21) is housed in the second opening.

### Supplementary Note 14

The semiconductor device (A30) according to supplementary note 13,
in which the first layer (121) has a first opening (121B) penetrating therethrough in the first direction (z),
the second opening (122B) overlaps the first opening when viewed in the first direction, and
the second opening is recessed from the first joining surface (101).

### Supplementary Note 15

The semiconductor device (A40) according to supplementary note 13,
in which the second opening (122B) penetrates the second layer (122) in the first direction (z).

### Supplementary Note 16

The semiconductor device (A40) according to supplementary note 15,
in which the first joining layer (21) is in contact with a portion of the first layer (121) exposed from the second opening (122B).

### Supplementary Note 17

The semiconductor device (A10) according to any one of supplementary notes 2 to 16, further including:
sealing resin (40) covering the semiconductor element (30),
in which the main part (11) has a mounting surface (112) facing the same side as the element surface (301) does in the first direction (z), and
the mounting surface is exposed from the sealing resin.

### Supplementary Note 18

The semiconductor device (A10) according to supplementary note 17,
in which the main part (11) has an end surface (113) facing a direction orthogonal to the first direction (z), and
the end surface is exposed from the sealing resin (40).

### Supplementary Note 19

The semiconductor device (A10) according to supplementary note 17,
in which the main part (11) includes a first terminal (10A) and a second terminal (10B) that are separated from each other in a direction orthogonal to the first direction (z),
the first metal layer (12) is laminated on the first terminal, and
the second metal layer (13) is laminated on the second terminal.

### Supplementary Note 20

The semiconductor device (A50) according to supplementary note 1,
in which the conductive member (10) has a loading surface (111) facing the element surface (301) and a first recessed part (14) and a second recessed part (15) that are recessed from the loading surface,
the first joining surface (101) defines the first recessed part, and
the second joining surface (102) defines the second recessed part.

### Supplementary Note 21

The semiconductor device (A10) according to supplementary note 20, in which a part of the first electrode (36) is housed in the first recessed part (14), and a part of the second electrode (37) is housed in the second recessed part (15).

### Supplementary Note 22

The semiconductor device (A10) according to supplementary note 3,
in which the second metal layer (13) is separated from the first metal layer (12).

### Supplementary Note 23

The semiconductor device (A10) according to supplementary note 4,
in which each of the first joining layer (21) and the second joining layer (22) contains tin.

### Supplementary Note 24

The semiconductor device (A10) according to supplementary note 4,
in which the first metal layer (12) and the second metal layer (13) contain the same metal elements, and each of the first metal layer and the second metal layer contains metal elements different from metal elements contained in the main part (11).

### Supplementary Note 25

The semiconductor device (A10) according to supplementary note 24,
in which the main part (11) contains copper, and
each of the first metal layer (12) and the second metal layer (13) contains nickel.

The present disclosure contains subject matter related to that disclosed in Japanese Priority Patent Application JP 2025-011385 filed in the Japan Patent Office on Jan. 27, 2025, the entire content of which is hereby incorporated by reference.

What is claimed is:

1. A semiconductor device comprising:
a conductive member; and
a semiconductor element that is positioned on one side of the conductive member in a first direction and is conductive to the conductive member,
wherein the semiconductor element has an element surface facing the conductive member, and a first electrode and a second electrode that are projecting from the element surface,
an area of the first electrode is larger than an area of the second electrode when viewed in the first direction,
a dimension of the first electrode in the first direction is smaller than a dimension of the second electrode in the first direction,
the conductive member has a first joining surface to which the first electrode is conductively joined and a second joining surface to which the second electrode is conductively joined, and
the first joining surface is positioned closer to the element surface than the second joining surface is in the first direction.

2. The semiconductor device according to claim 1,
wherein the conductive member has a main part containing metal, and a first metal layer and a second metal layer that are laminated on one side of the main part in the first direction,
the first metal layer includes the first joining surface, and
the second metal layer includes the second joining surface.

3. The semiconductor device according to claim 2,
wherein a dimension of the first metal layer in the first direction is larger than a dimension of the second metal layer in the first direction.

4. The semiconductor device according to claim 3, further comprising:
a first joining layer for conductively joining the first joining surface and the first electrode to each other; and
a second joining layer for conductively joining the second joining surface and the second electrode to each other,
wherein the first joining layer and the second joining layer contain same metal elements.

5. The semiconductor device according to claim 4,
wherein the first metal layer has a first layer laminated on the main part and a second layer that is positioned opposite to the main part with the first layer interposed therebetween and is laminated on the first layer, and
the second layer includes the first joining surface.

6. The semiconductor device according to claim 5,
wherein the second layer is positioned on an inner side than the first layer when viewed in the first direction.

7. The semiconductor device according to claim 6,
wherein a dimension of the second layer in the first direction is larger than a dimension of the first layer in the first direction.

8. The semiconductor device according to claim 6,
wherein the first layer includes a portion protruding on an outer side than the first electrode when viewed in the first direction.

9. The semiconductor device according to claim 8,
wherein a peripheral edge of the first electrode overlaps a peripheral edge of the second layer when viewed in the first direction.

10. The semiconductor device according to claim 8,
wherein the second layer is positioned on an inner side than the first electrode when viewed in the first direction.

11. The semiconductor device according to claim 8,
wherein the second layer has a second end surface facing a direction orthogonal to the first direction, and
the second end surface is covered with the first joining layer.

12. The semiconductor device according to claim 11,
wherein the first layer has a first end surface facing a direction orthogonal to the first direction, and
the first end surface is exposed from the first joining layer.

13. The semiconductor device according to claim
wherein the second layer has a second opening opening from the first joining surface, and
a part of the first joining layer is housed in the second opening.

14. The semiconductor device according to claim 13,
wherein the second opening penetrates the second layer in the first direction.

15. The semiconductor device according to claim 14,
wherein the first joining layer is in contact with a portion of the first layer exposed from the second opening.

16. The semiconductor device according to claim 13,
wherein the first layer has a first opening penetrating therethrough in the first direction,
the second opening overlaps the first opening when viewed in the first direction, and
the second opening is recessed from the first joining surface.

17. The semiconductor device according to claim 2, further comprising:
sealing resin covering the semiconductor element,
wherein the main part has a mounting surface facing a same side as the element surface does in the first direction, and
the mounting surface is exposed from the sealing resin.

18. The semiconductor device according to claim 17,
wherein the main part has an end surface facing a direction orthogonal to the first direction, and
the end surface is exposed from the sealing resin.

19. The semiconductor device according to claim 17,
wherein the main part includes a first terminal and a second terminal that are separated from each other in a direction orthogonal to the first direction,
the first metal layer is laminated on the first terminal, and
the second metal layer is laminated on the second terminal.
